(19) United States
(12) Patent Application Publication
(10) Pub. No.: US 2026/0136666 A1
(43) Pub. Date: May 14, 2026

(54) DISPLAY DEVICE

(71) Applicant: LG Display Co., Ltd., Seoul (KR)

(72) Inventor: Ji Hwan JUNG, Paju-si (KR)

(73) Assignee: LG Display Co., Ltd., Seoul (KR)

(21) Appl. No.: 19/344,882

(22) Filed: Sep. 30, 2025

(30) Foreign Application Priority Data
Nov. 11, 2024 (KR) 10-2024-0159598

(51) Int. Cl. H10D 86/40; H10D 86/60

(52) U.S. Cl. CPC H10D 86/411; H10D 86/423; H10D 86/425; H10D 86/60

(57) ABSTRACT

A display device can include a substrate including a display area and a non-display area surrounding the display area, a sensor portion provided in the display area, a plurality of first transistors provided in the display area on the substrate and configured to include oxide semiconductor layers, respectively, and a hydrogen capture pattern located in the sensor portion and disposed adjacent to an oxide semiconductor layer of at least one of the plurality of first transistors.

### CROSS-REFERENCE TO RELATED APPLICATION

This application claims priority to Korean Patent Application No. 10-2024-0159598, filed in the Republic of Korea on November 11, 2024, which is hereby incorporated by reference as if fully set forth herein.

### BACKGROUND

### Field of the Disclosure

The present disclosure relates to a display device, and more particularly, to a light emitting display device capable of improving sensitivity of a sensor portion and reliability of internal elements.

### Discussion of the Related Art

Display devices that display images, such as TVs, monitors, smartphones, tablets, and laptops, are used in various ways and forms convey information.

A display device among the display devices can include a plurality of pixels to display an image and has transistors to control an operation of each pixel to generate the image.

Also among the display devices, light emitting display devices having a light emitting device that is able to self-emit light in the display panel without a separate light source for compactness of the device and clear color display are being considered as competitive applications.

A light emitting device that is able to self-emit light can include an anode and a cathode, which face each other as electrodes, and an emission layer between the anode and the cathode, and can include a common layer for transferring holes and electrons to the emission layer.

Meanwhile, recent application of display devices is considering structures that include sensor portions for various purposes, and a variety of research and development is being conducted thereon to provide useful applications of the display devices.

### SUMMARY OF THE DISCLOSURE

An object of the present disclosure is to provide a light emitting display device with improved sensitivity of a sensor portion.

Another object of the present disclosure is to provide a light emitting display device capable of improving the reliability of a transistor.

Still another object of the present disclosure is to provide a display device further including a configuration capable of preventing or reducing influences caused by hydrogen, etc. generated from an array structure such as an adjacent thin film transistor, etc. in a transmissive area that does not have a configuration of metal, thereby improving reliability of the transmissive area and increasing the transmittance in the transmissive area.

Yet another object of the present disclosure is to provide a display device having improved reliability by further providing a hydrogen capture pattern capable of preventing or reducing hydrogen generated during a process from causing operational deterioration of elements due to movement between insulating films.

Still yet another object of the present disclosure is to provide a display device in which a hydrogen capture pattern capable of reducing the element failure rate due to the flow of hydrogen that can affect operation of elements can be formed without providing an additional layer, thus reducing the amounts of materials used throughout the manufacturing process, such as gas, etchant, etc. for manufacturing the display device, thereby reducing generation of greenhouse gases during the manufacturing process.

An embodiment of the present disclosure provides a display device including a substrate including a display area and a non-display area surrounding the display area, a sensor portion provided in the display area, a plurality of first transistors provided in the display area on the substrate and configured to include an oxide semiconductor layer, and a hydrogen capture pattern located on the sensor portion and disposed adjacent to the oxide semiconductor layer of the first transistors.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view showing a display device according to an embodiment of the present disclosure;

FIG. 2 is an enlarged view showing area A1 of FIG. 1;

FIG. 3 is a circuit diagram of the first and second sub-pixels of FIG. 1;

FIG. 4 is a cross-sectional view taken along line I-I’ of FIG. 2;

FIG. 5 is a graph showing the wavelength-dependent transmittance of a hydrogen capture pattern included in embodiments of the present disclosure;

FIG. 6 is a cross-sectional view showing a transistor and a hydrogen capture pattern provided in an area of an infrared sensor according to an embodiment of the present disclosure;

FIG. 7 is a graph showing the I-V characteristics of transistors in the display area of the sensor portion and the non-sensor portion in a display device without a hydrogen capture pattern;

FIG. 8 is a graph showing the I-V characteristics of a transistor in a transmissive area of a display device having a hydrogen capture pattern in the transmissive area according to an embodiment of the present disclosure;

FIG. 9 is a cross-sectional view showing a display device according to an embodiment of the present disclosure; and

FIGS. 10 to 12 are cross-sectional views of the transmissive area according to various embodiments of the present disclosure.

### DETAILED DESCRIPTION OF THE EMBODIMENTS

Hereinafter, a detailed description will be given of example embodiments of the present disclosure in conjunction with the attached drawings.

Reference will now be made in detail to example embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same can obscure the subject matter of the disclosure. In addition, the names of elements used in the following description are selected in consideration of clarity of description of the disclosure, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and need not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise. The term "can" fully encompasses all the meanings and coverages of the term "may."

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

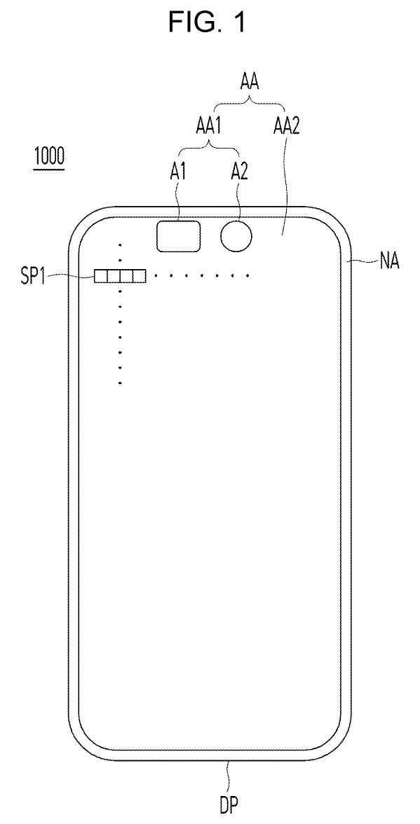

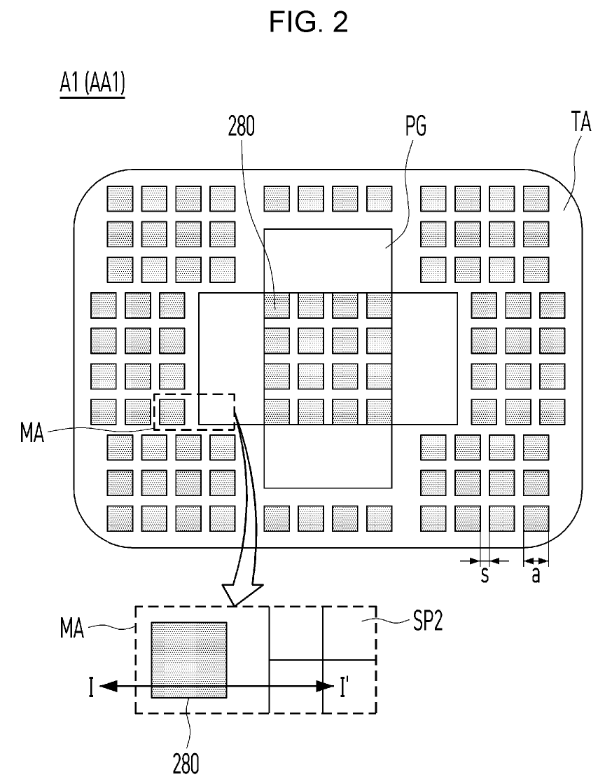

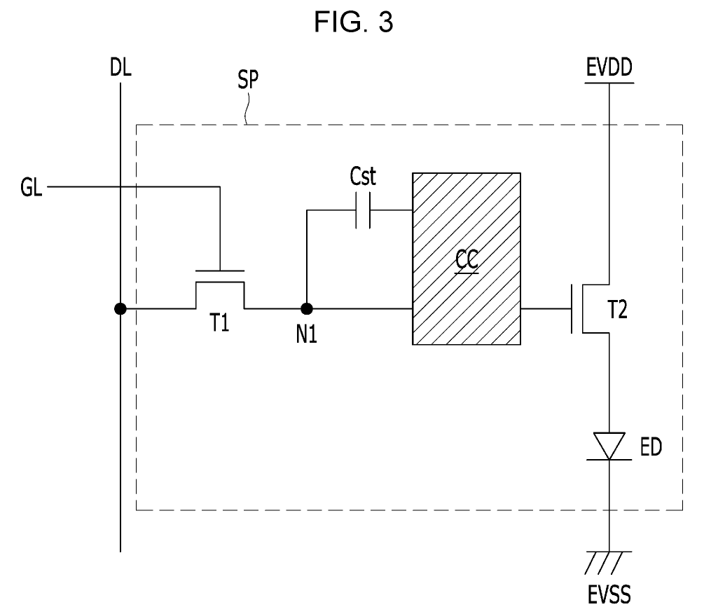

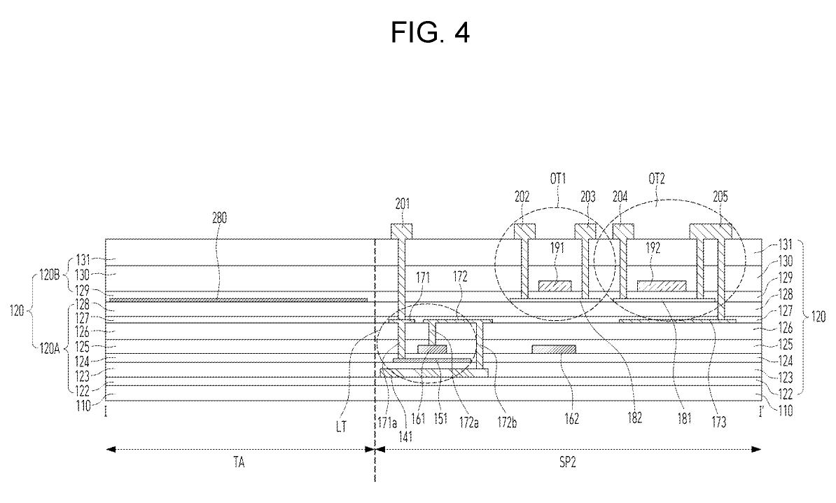

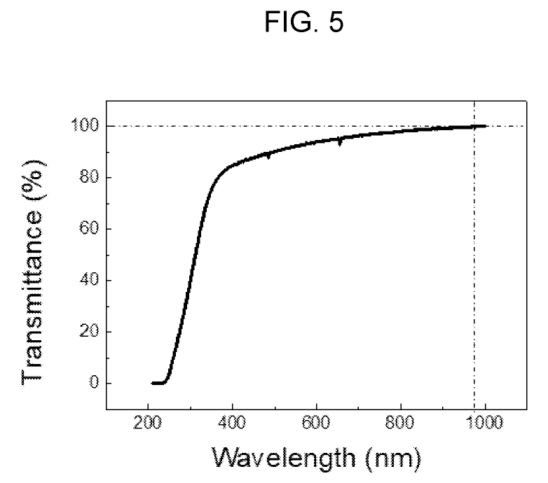

FIG. 1 is a plan view showing a display device according to an embodiment of the present disclosure. FIG. 2 is an enlarged view showing area A1 of FIG. 1. FIG. 3 is a circuit diagram of the first and second sub-pixels of FIG. 1. FIG. 4 is a cross-sectional view taken along line I-I’ of a magnified area MA in FIG. 2. FIG. 5 is a graph showing the wavelength-dependent transmittance of a hydrogen capture pattern included in embodiments of the present disclosure. All components of each display device according to all embodiments of the present disclosure are operatively coupled and configured.

As shown in FIG. 1, a display device 1000 according to an embodiment of the present disclosure includes a display panel DP, and the display panel DP can include a substrate 110 (FIG. 4) including a display area AA and a non-display area NA surrounding the display area AA, and a driving portion connected to the substrate 110. The driving portion can be integrated along with an array configuration provided in the display area AA on the substrate 110, or can be connected to the substrate 110 using a COG (chip-on-glass) method, or can include a printed circuit board connected to the substrate 110 through a film or connector using a COF (chip-on-film) method.

The display area AA is an area where an image is displayed. A plurality of sub-pixels SP is arranged in the display area AA of the display panel DP, and an image can be displayed using the sub-pixels SP. The display area AA can be called as ‘an active area’ and the non-display area NA can be called as ‘non-active area’ in this description.

The display device 1000 can include a display panel DP and a case that accommodates a side of the display panel DP and a bottom of the display panel DP. The non-display area NA of the display panel DP can be hidden by the case or can be covered with a separate printed film. A printed circuit film and/or a battery can be included between the bottom of the display panel DP and the case.

The display panel DP includes a substrate 110 and an array configuration on the substrate 110. The substrate 110 can be formed of a flexible plastic material and thus can have flexible characteristics. For example, the substrate 110 can include first and second organic films overlapping each other with an inorganic interlayer insulating film therebetween. The first and second organic films can include, for example, polyimide. The first and second organic films can include different organic films, in addition to polyimide. As another example, the substrate 110 can include a thin glass material having flexibility.

The substrate 110 can include the first and second organic films, any one of which is a PET (polyethylene terephthalate) film and the remaining one of which is a polyimide film. When the first and second organic films of the substrate 110 are made of different organic materials, an adhesive film such as a pressure sensitive adhesive (PSA) film can be included therebetween.

The substrate 110 serves to support and protect the components of the display device 1000 disposed thereon. The substrate 110 can include a display area AA that displays an image and a non-display area NA excluding the display area AA.

The area where sub-pixels SP such as first and second sub-pixels SP1, SP2 are arranged can be the display area AA (the active area), and an area excluding the display area AA can be a non-display area NA.

The non-display area NA may be disposed outside the display area AA. The non-display area NA can be disposed in the edge area surrounding the display area AA that displays an image. At least one driving portion configured to drive the sub-pixels SP can be disposed in the non-display area NA. The driving portion can include a gate-in-panel GIP. The gate-in-panel GIP can be connected to a plurality of gate lines GL of the active area AA and can be configured to sequentially supply gate voltage signals to the gate lines GL. The gate-in-panel GIP can further include transistors of the same stack as those provided in the sub-pixels SP.

In the non-display area NA, various additional components can be further disposed to drive the sub-pixels SP such as first and second sub-pixels SP1, SP2 in the display area AA.

The display device 1000 according to an embodiment of the present disclosure can include, as shown in FIG. 1, the display area AA including a first area AA1 including a plurality of sensor portions A1, A2 and a second area AA2 having no sensor portion. Therefore, the display area AA can serve to sense various functions, as well as the display function.

The second area AA2 having no sensor portion includes a plurality of first sub-pixels SP1. The first area AA1 having sensor portions includes a plurality of second sub-pixels SP2 and a transmissive area TA. In the first area AA1 having the transmissive area TA, no light shielding material or the like is disposed in the area where the transmissive area TA is located. The arrangement density of the first sub-pixels SP1 in the second area AA2 having no sensor portion can be greater than the arrangement density of the second sub-pixels SP2 in the first area AA1 including the sensor portions A1, A2. The resolution of the first area AA1 including the sensor portions A1, A2 can be lower than the resolution of the second area AA2.

Each of the sensor portions A1, A2 can include a transmissive area TA to increase the sensitivity of light at various wavelengths. The sensor portions A1, A2 are provided for various purposes and can include, for example, an infrared sensor, an ambient light detection sensor, a fingerprint recognition sensor, a camera, a biometric sensor, etc. Although the two sensor portions are illustrated in FIG. 1, the embodiments of the present disclosure are not limited thereto. In modifications of embodiments of the present disclosure, three or more sensor portions can be provided.

The sensor portions A1, A2 serve to sense light coming from the top of the substrate 110, and the sensing accuracy can vary depending on the quantity of light received. Accordingly, the area where the sensor portions A1, A2 are disposed does not overlap the light shielding metal, so that light coming from the outside can be collected by each sensor unhindered. The sensor portions A1, A2 are located in the display area AA and have a display function in addition to the sensing operation, so a plurality of second sub-pixels SP2 can be included therein, as shown in FIG. 2. Wires such as gate lines, data lines, power voltage lines, etc. for driving the second sub-pixels SP2 included in the sensor portions A1, A2 can be arranged by bypassing the outer periphery of the sensor portions A1, A2. In order to obtain a sufficient quantity of received light by external light sensing in the sensor portions A1, A2, an area where no second sub-pixel SP2 is disposed can be designated as a transmissive area TA. The transmissive area TA can have no light shielding metal material. As such, the second sub-pixels SP2 included in the sensor portions A1, A2 are locally arranged in the sensor portions A1, A2 and the second sub-pixels SP2 can be directly connected to the gate lines, data lines, power voltage lines, etc. in an area excluding the transmissive area TA.

In the sensor portions A1, A2, a plurality of second sub-pixels SP2 can be locally arranged to form groups. The groups of second sub-pixels SP2 in the sensor portions A1, A2 function as emissive portion placement areas PG in the sensor portions A1, A2. The emissive portion placement area PG can be disposed so as not to overlap the transmissive area TA.

A plurality of emissive portion placement areas PG can be spaced apart from each other in the sensor portions A1, A2. As shown in FIG. 2, the transmissive area TA can be disposed between the emissive portion placement areas PG. In some cases, when the emissive portion placement areas PG are disposed outside of the four sides of a square at the center, an alignment key can be disposed in the square inside the emissive portion placement areas PG to align the positions of the sensor portions A1, A2 in a certain part of the display area AA of the display panel DP. In embodiments of the present disclosure, a shape of the emissive portion placement areas PG or a shape of the arrangement of the hydrogen capture pattern 280 can be a shape other than rectangular, such as circular, semicircular, polygonal or other, but is not limited thereto.

The display device 1000 according to an embodiment of the present disclosure further includes a hydrogen capture pattern 280 in the transmissive area TA. The hydrogen capture pattern 280 in the transmissive area TA disposed in the sensor portions A1, A2 can have transmittance depending on the wavelength of light detected by the sensor portions A1, A2. For example, when the first sensor portion A1 is provided with an infrared sensor, the hydrogen capture pattern 280 can be made of a material with high transmittance in the infrared wavelength range. For example, when the second sensor portion A2 is provided with a camera, the hydrogen capture pattern 280 can be made of a material with high transmittance in the visible spectrum. In some cases, an ultraviolet sensor configured to sense ultraviolet light in the display area AA can be additionally provided as a configuration different from that of the first and second sensor portions A1, A2. The sensor portions A1, A2 can be disposed below the substrate 110, but the present disclosure is not limited thereto. The sensor portions A1, A2 can be formed by inserting the same into the substrate 110, and the configuration of the sub-pixels formed on the substrate 110 further include the function of the sensor portions A1, A2.

A plurality of hydrogen capture patterns 280 can be disposed in the transmissive area TA. The hydrogen capture patterns 280 function to block hydrogen generated or flowing in the lower insulating film, and the hydrogen blocking function can be strengthened by making the width “a” of each hydrogen capture pattern 280 greater than the spacing “s” between the hydrogen capture patterns 280.

The inventors of the present disclosure have ascertained that, when the hydrogen capture patterns 280 are made of indium zinc oxide among indium oxides, a transmittance is 99% or more in the infrared wavelength range, namely at a wavelength of about 900 nm, as shown in FIG. 5. The hydrogen capture patterns 280 can serve to capture hydrogen generated in the array to stabilize the function of the transistors of adjacent sub-pixels and maintain light transmittance in the sensor portion or the transmissive area TA.

Meanwhile, hydrogen can be generated during formation of insulating films 120 such as first to tenth insulating films 122, 123, 124, 125, 126, 127, 128, 129, 130, 131 on the substrate 110, as shown in FIG. 4, or during the hydrogenation process of a first active layer 151 or the heat treatment process after film formation. Since the formation of the insulating films 120 such as first to tenth insulating films 122, 123, 124, 125, 126, 127, 128, 129, 130, 131 is performed individually, when hydrogen is included in the insulating film in a deposition chamber during formation of each insulating film, hydrogen remaining in the insulating film does not flow significantly. The first active layer 151 can be hydrogenated by filling the pores in the first active layer 151 with hydrogen remaining in the third to fifth insulating films 124, 125, 126 adjacent to the upper side of the first active layer 151 and the second insulating film 123 adjacent to the lower side of the first active layer 151 through heat treatment in order to increase carrier mobility in the polycrystalline silicon semiconductor layer. To this end, the second to fifth insulating films 123, 124, 125, 126 can include a silicon nitride film having high hydrogen content.

A silicon nitride film has excellent barrier properties but contains more hydrogen than a silicon oxide film. Therefore, during the heat treatment process required for manufacturing the first and second oxide transistors OT1, OT2, hydrogen remaining in the second to fifth insulating films 123, 124, 125, 126 located below the second and third active layers 182, 181 of the first and second oxide transistors OT1, OT2 can flow and escape upward.

The flow of hydrogen is random. In particular, the transmissive area TA has no light shielding metal. Since no light shielding metal is disposed on each of the first to tenth insulating films 122, 123, 124, 125, 126, 127, 128, 129, 130, 131 located on the substrate 110, hydrogen passing through the second to fifth insulating films 123, 124, 125, 126 of the polycrystalline transistor LT can flow radially and can be intensively applied to the transmissive area TA.

The display device 1000 according to embodiments of the present disclosure is configured such that the insulating films 120 disposed on the substrate 110 are divided into a first insulating film group 120A located at the lower position and a second insulating film group 120B located at the upper position, based on the second and third active layers 182, 181 made of oxide semiconductor layers, and a hydrogen capture pattern 280 is provided between the first and second insulating film groups 120A, 120B in the transmission area TA. When the hydrogen capture pattern 280 is located on the first insulating film group 120A, hydrogen that remains in the first insulating film group 120A and flows upward can be captured by the hydrogen capture pattern 280 with good hydrogen capture capability, and abnormal operation of the first and second oxide transistors OT1, OT2 for hydrogen can be prevented or reduced.

In addition, the second light shielding pattern 162 of the first oxide transistor OT1 and the third light shielding pattern 173 of the second oxide transistor OT2 can include, for example, a metal such as titanium, etc. having hydrogen capture characteristics, thus blocking transfer of hydrogen from the first insulating film group 120A to the second and third active layers 182, 181 in the vertical direction.

The seventh insulating film 128 in direct contact with the lower side of the second active layer 182 of the first oxide transistor OT1 and the third active layer 181 of the second oxide transistor OT2, or the sixth and seventh insulating films 127, 128 can include a silicon oxide film having lower hydrogen content than a silicon nitride film, enabling interlayer blockage of hydrogen generated from the first to fifth insulating films 122, 123, 124, 125, 126 of the polycrystalline transistor LT.

Since the transistor arrangement density in the transmissive area TA is low or zero, a passage through which a large amount of hydrogen can move can be formed. In embodiments of the present disclosure, the hydrogen capture pattern 280 can be provided in the transmissive area TA, so hydrogen generated from the polycrystalline transistor LT can be captured by the hydrogen capture pattern 280 in the transmissive area TA, blocking the flow of hydrogen and preventing or reducing transfer of hydrogen to the oxide transistors OT1, OT2.

The first area AA1 where the sensor portions A1, A2 are located includes a transmissive area TA that does not have a light shielding metal or a second sub-pixel SP2, and thus has a lower transistor arrangement density than the second area AA2 where the first sub-pixels SP1 are densely arranged.

The second sub-pixel SP2 of the first area AA1 including the sensor portions A1, A2 and the first sub-pixel SP1 of the second area AA2 having no sensor portion can include the same circuit configuration, for example, as shown in FIG. 3. In some cases, the first area AA1 of the sensor portions A1, A2 and the second area AA2 having no sensor portion can compensate for the luminance of the area including the transmissive area TA with a small number of transistors in the sensor portions A1, A2 with a relatively low arrangement density depending on the difference in the transistor arrangement density. For example, the size of the light emitting device or the size of the transistor of at least one second sub-pixel SP2 in the first area AA1 can be increased. Alternatively, even when the transistors of the second sub-pixel SP2 of the first area AA1 including the sensor portions A1, A2 and the first sub-pixel SP1 in the second area AA2 where the sensor portions are not disposed can have the same layer structure, the width/length of at least one active layer or the carrier mobility can be varied. However, the embodiments of the present disclosure are not limited thereto.

The hydrogen capture pattern 280 included in the transmissive area TA can be disposed adjacent to the second sub-pixels SP2 at a low arrangement density in the sensor portions A1, A2, preventing or reducing hydrogen from flowing into the side of the second sub-pixels SP2 to the second active layer 182 of the first oxide transistor OT1 and the third active layer 181 of the second oxide transistor OT2. When the hydrogen capture pattern 280 has higher hydrogen capture capability than the second and third active layers 182, 181, hydrogen blockage of the second and third active layers 182, 181 by the hydrogen capture pattern 280 is further strengthened.

Embodiments of the present disclosure are not limited to a configuration in which the transmissive area TA is disposed in the sensor portions A1, A2. For example, a transmissive area TA can be disposed in the second area AA2 having no sensor portion, and a hydrogen capture pattern 280 can also be provided in the transmissive area TA. Briefly, the hydrogen capture pattern 280 having high transmittance can be disposed in the transmissive area TA of a transparent display device. As such, the hydrogen capture pattern 280 disposed in the transmissive area TA of the transparent display device can be made of a material having high transmittance in the visible spectrum, for example, at a wavelength of 400 nm to 700 nm. For example, when the hydrogen capture pattern 280 is made of indium oxide, as shown in FIG. 5, the hydrogen capture pattern 280 can have a transmittance of about 85% or more.

Examples of the indium oxide used for the hydrogen capture pattern 280 include indium oxide, indium zinc oxide, indium gallium oxide, and indium gallium zinc oxide. However, in embodiments of the present disclosure, the material for the hydrogen capture pattern 280 is not be limited to indium oxide. The material for the hydrogen capture pattern 280 can vary depending on the wavelength of light received or sensed by the sensor portions A1, A2. When the sensor portion has light receiving properties for any one wavelength of infrared light IR, visible light, and ultraviolet light, a material that selectively transmits light at the corresponding wavelength can be used.

Meanwhile, the hydrogen capture pattern 280 provided in the transmissive area TA can be disposed planarly adjacent to the second active layer 182 of the first oxide transistor OT1 or the third active layer 181 of the second oxide transistor OT2 disposed in the second sub-pixels SP2 in the transmissive area TA in the sensor portions A1, A2. In embodiments of the present disclosure, the hydrogen capture pattern 280 can be located on a same layer or coplanar to the second and third active layers 182, 181 of the first and second oxide transistors OT1, OT2.

The sub-pixel SP including the first and second sub-pixels SP1, SP2 in the active area AA can include, for example, a first transistor T1, a second transistor T2, a storage capacitor Cst, a compensation circuit CC, and a light emitting device ED, as shown in FIG. 3.

For example, the first transistor T1 can be a switching transistor and the second transistor T2 can be a driving transistor.

A first electrode (e.g., a drain electrode) of the first transistor T1 is electrically connected to a data line DL, and a second electrode (e.g., a source electrode) thereof is electrically connected to a first node N1. A gate electrode of the first transistor T1 is electrically connected to a gate line GL. The first transistor T1 serves to transmit a data signal supplied through the data line DL to the first node N1 in response to a scan signal supplied through the gate line GL.

The storage capacitor Cst is electrically connected to the first node N1, charging the voltage applied to the first node N1.

A first electrode (e.g., a drain electrode) of the second transistor T2 receives a high potential driving voltage EVDD, and a second electrode (e.g., a source electrode) thereof is electrically connected to a first electrode (e.g., an anode) of the light emitting device ED. The second transistor T2 can serve to control the quantity of driving current flowing to the light emitting device ED in response to voltage applied to the gate electrode.

The semiconductor layer of the first transistor T1 and/or the second transistor T2 can include silicon such as amorphous silicon (a-Si), polycrystalline silicon (poly-Si), or low-temperature polycrystalline silicon (poly-Si), or can include an oxide such as IGZO (indium-gallium-zinc-oxide), but the present disclosure is not limited thereto. At least one of the first transistor T1 or the second transistor T2 can include an oxide semiconductor layer, enabling formation at a low temperature compared to when using other materials, maintaining amorphous characteristics, and exhibiting high carrier mobility.

The light emitting device ED serves to output light corresponding to the driving current. The light emitting device ED is able to output light corresponding to any one color selected from among red, green, blue, and white.

The light emitting device ED can include an anode, an emission layer disposed on the anode, and a cathode configured to be connected to a low potential driving voltage EVSS or a common voltage. The emission layer can be provided to emit light of the same color for each sub-pixel SP, such as white light, or to emit light of a different color for each sub-pixel SP, such as red, green, or blue light.

The light emitting device ED can be a top emission diode or a bottom emission diode.

The compensation circuit CC can be provided in the sub-pixel SP to compensate for the threshold voltage of the second transistor T2, etc. The compensation circuit CC can be composed of one or more transistors. The compensation circuit CC can include one or more transistors and capacitors and can be configured in various ways depending on the compensation method. A sub-pixel including the compensation circuit CC can include circuits with various structures having different numbers of transistors and/or capacitors, such as 3T1C, 4T2C, 5T2C, 6T1C, 6T2C, 7T1C, 7T2C, etc.

FIG. 4 shows a second sub-pixel SP2 including both a polycrystalline transistor LT and oxide transistors OT1, OT2. The sub-pixel of FIG. 4 represents a second sub-pixel SP2 adjacent to the transmissive area TA. The first sub-pixels SP1 in the second area AA2 where the sensor portions A1, A2 are not disposed can also have the same configuration as the second sub-pixel SP2 of FIG. 4.

As shown in FIG. 4, the polycrystalline transistor LT can include a first active layer 151 made of polycrystalline silicon on the substrate 110, a first gate electrode 161 overlapping the first active layer 151, and a first source drain electrode 171 spaced apart from the first gate electrode 161 and provided above the first active layer 151.

A first light shielding pattern 141 can be provided below the first active layer 151 of the polycrystalline transistor LT to prevent light from being incident on the first active layer 151 due to light on the lower side of the substrate 110.

The polycrystalline transistor LT illustrated in FIG. 4 shows, for example, a state in which the first gate electrode 161 and the first light shielding pattern 141 are electrically connected by the first connection electrode 172. When the first light shielding pattern 141 and the first gate electrode 161 are electrically connected, rapid operation can be easily achieved and on-current can be increased by dual gate driving. However, the shape of the polycrystalline transistor LT in the display device 1000 according to an embodiment of the present disclosure is not limited thereto. Another source drain electrode may be connected to the first active layer 151. The first source drain electrode 171 and another source drain electrode may be positioned symmetrically with respect to the first active layer 151.

A first insulating film 122 that functions as a buffer layer can be provided between the substrate 110 and the first light shielding pattern 141, thereby preventing or reducing impurities included in the substrate 110 or impurities introduced from the lower side through the substrate 110 from being transferred to the upper array.

The first and second oxide transistors OT1, OT2 can be located at least above the first active layer 151 of the polycrystalline transistor LT. This is to form the oxide transistors OT1, OT2 after completion of crystallization, so as to prevent or reduce the heat generated during crystallization from affecting the oxide transistors OT1, OT2 when performing a thermal process at a temperature higher than or equal to a certain temperature for crystallization after the first active layer 151 of the polycrystalline transistor LT is formed in an amorphous state on the substrate 110.

The first and second oxide transistors OT1, OT2 provided in the second sub-pixel SP2 can have different structures depending on the characteristics. The first oxide transistor OT1 can include a second active layer 182 made of an oxide semiconductor, a second gate electrode 191 overlapping the second active layer 182, and second and third source drain electrodes 202, 203 spaced apart from the second gate electrode 191 and provided at both sides of the second active layer 182. The second oxide transistor OT2 can include a third active layer 181 made of an oxide semiconductor, a third gate electrode 192 overlapping the third active layer 181, and fourth and fifth source drain electrodes 204, 205 spaced apart from the third gate electrode 192 and provided at both sides of the third active layer 181. The first and second oxide transistors OT1, OT2 can have different characteristics by adjusting the distances from the second light shielding pattern 162 and the third light shielding pattern 173 provided below the second and third active layers 182, 181 and/or the connection between the third light shielding pattern 173 and the fifth source drain electrode 205.

In some cases, the first oxide transistor OT1 can serve to increase on-current by connecting the second gate electrode 191 and the second light shielding pattern 162 and can have high-rate characteristics.

The second light shielding pattern 162 of the first oxide transistor OT1 can be located on the same layer as the first gate electrode 161 of the polycrystalline transistor LT, and the third light shielding pattern 173 of the second oxide transistor OT2 can be located on the same layer as the first source drain electrode 171 and the first connection electrode 172 of the polycrystalline transistor LT.

According to an embodiment of the present disclosure, the second and third active layers 182, 181 of the first and second oxide transistors OT1, OT2 can have different carrier mobilities. For example, the second active layer 182 can have higher carrier mobility than the third active layer 181. To vary the carrier mobility, the second active layer 182 can further include an oxide semiconductor layer compared to the third active layer 181.

With references to the figures, including FIG. 2, the first sensor portion A1 can include the transmissive area TA and the emissive portion placement area PG. In embodiments of the present disclosure, a size of an area of the transmissive area TA can be different from a size the emissive portion placement area PG. For example, the size of the area of the transmissive area TA can be greater than the size the emissive portion placement area PG, but is not limited thereto. Also, the size of the area of the transmissive area TA can be different from a size of areas of the hydrogen capture pattern 280. For example, the size of the area of the transmissive area TA can be greater than the size of areas of the hydrogen capture pattern 280, but is not limited thereto. That is, a combined size of areas of the hydrogen capture pattern 280 can be less than that of the transmissive area TA. Additionally, the combined size of areas of the hydrogen capture pattern 280 can be greater than the size the emissive portion placement area PG.

In embodiments of the present disclosure, a size of pieces of the hydrogen capture pattern 280 can be different from a size of area of at least one of the first active layer 151, the second active layer 182 and the third active layer 181. For example, some or all of the pieces of the hydrogen capture pattern 280 can be greater than the size of area of the at least one of the first active layer 151, the second active layer 182 and the third active layer 181, or can be smaller than the size of area of the at least one of the first active layer 151, the second active layer 182 and the third active layer 181. In other embodiments of the present disclosure, some of the pieces of the hydrogen capture pattern 280 can be greater than the size of area of the at least one of the first active layer 151, the second active layer 182 and the third active layer 181 and some of the pieces of the hydrogen capture pattern 280 can be less than the size of area of the at least one of the first active layer 151, the second active layer 182 and the third active layer 181.

In embodiments of the present disclosure, size or areas of the pieces of the hydrogen capture pattern 280 can be different from each other. For example, some of the pieces of the hydrogen capture pattern 280 can be larger or smaller than other pieces of the hydrogen capture pattern 280. In embodiments of the present disclosure, different sized piece of the hydrogen capture pattern 280 can be arranged based on a particular pattern in the transmissive area TA. For example, larger pieces of the hydrogen capture pattern 280 can be arranged closer to the emissive portion placement area PG or the second subpixel SP2 or vice-versa. In other embodiments of the present disclosure, smaller sized pieces of the hydrogen capture pattern 280 can be located between adjacent larger pieces of the hydrogen capture pattern 280, but is not limited thereto. Additionally, the second sub-pixel SP2 can be located in the emissive portion placement area PG. In embodiments of the present disclosure, the hydrogen capture pattern 280 can encircle the emissive portion placement area PG in the first sensor portion A1, or the emissive portion placement area PG can encircle the hydrogen capture pattern 280, or both.

Additionally, pieces of the hydrogen capture pattern 280 can have different thicknesses or a thickness within a piece can vary to have different thicknesses. For example, smaller sized pieces of the hydrogen capture pattern 280 can have a greater thickness than larger sized pieces of the hydrogen capture pattern 280, or vice-versa. When a piece of the hydrogen capture pattern 280 have different thicknesses internally, a thicker portion can be located at the periphery while a thinner portion can be located in the middle of the piece or vice-versa, but is not limited thereto.

In embodiments of the present disclosure, the various pieces of the hydrogen capture pattern 280 can have different hydrogen capture capability based on different density or constituent materials, for example, but is not limited thereto.

In embodiments of the present disclosure, a pattern or arrangement of the pieces of hydrogen capture pattern 280 can vary. For example, the pieces of hydrogen capture pattern 280 need not be arranged in a matrix pattern but can be arranged in a circular pattern or other patterns, but is not limited thereto.

The polycrystalline transistor LT and the first oxide transistor OT1 can be the first transistor T1 shown in FIG. 3 or a switching transistor capable of rapid operation. The polycrystalline transistor LT and the first oxide transistor OT1 can receive an EM signal from the emission control line or a scan signal from the gate line GL. The second oxide transistor OT2 having the third active layer 181 with lower carrier mobility than the second active layer 182 is able to obtain a certain range of change in gate voltage (Vgs) from the off state to the on state in the I-V graph and facilitates expression of gray scales, and can thus function as a driving transistor configured to supply driving current to a light emitting device ED. In the sub-pixel SP of FIG. 3, the second oxide transistor OT2 can function as the second transistor T2.

In FIG. 4, the fifth source drain electrode 205 connected to the third active layer 181 of the second oxide transistor OT2 is shown as being connected to the third light shielding pattern 173 that extends further from one side than the third active layer 181 and is located lower than the third active layer 181. As such, the potential of the third light shielding pattern 173 can be stabilized and the influence of parasitic capacitance of the third active layer 181 can be prevented or reduced. This configuration can be exemplary, and in some cases, the third active layer 181 and the third light shielding pattern 173 can be electrically separated from each other.

As shown in FIG. 4, the hydrogen capture pattern 280 provided in the transmissive area TA can be located on the same layer as the second and third active layers 182, 181 of the first and second oxide transistors OT1, OT2, but embodiments of the present disclosure are not limited thereto. For example, the hydrogen capture pattern 280 provided in the transmissive area TA can be located on different layers from the second and third active layers 182, 181 of the first and second oxide transistors OT1, OT2, such as layers over or under a layer or layers having the second and third active layers 182, 181 of the first and second oxide transistors OT1, OT2.

As such, the hydrogen capture pattern 280 can include the same material as the oxide semiconductor layer of the second and third active layers 182, 181. However, the display device according to an embodiment of the present disclosure is not limited thereto. The material for the hydrogen capture pattern 280 can be replaced with any material that has a hydrogen capture function but does not impair the light receiving sensitivity of the sensor portions A1, A2 or the transmittance of the transmissive area TA. In some cases, the hydrogen capture pattern 280 can include a material having higher hydrogen capture capability than the second and third active layers 182, 181. The hydrogen capture pattern 280 can be formed by changing the composition ratio of the oxide semiconductor or adjusting the thickness when forming the second and third active layers 182, 181, thus increasing the transmittance of light at a certain wavelength.

The transmissive area TA where the hydrogen capture pattern 280 is located is an area where no light shielding metal is disposed. When hydrogen generated from the array in the adjacent sub-pixel SP1 flows upward, the hydrogen is captured by the hydrogen capture pattern 280 with excellent hydrogen capture capability, thereby preventing operational deterioration of the oxide transistors OT1, OT2 including the oxide semiconductor around or on the hydrogen capture pattern 280.

The polycrystalline transistor LT and the first and second oxide transistors OT1, OT2 include insulating films to insulate between the first to third light shielding patterns 141, 162, 173 and the first to third active layers 151, 182, 181, between the first to third active layers 151, 182, 181 and the first to third gate electrodes 161, 191, 192, and between the first to third gate electrodes 161, 191, 192 and the first source drain electrode 171 and second to the fifth source drain electrodes 202, 203, 204, 205.

Referring to FIG. 4, the layer structure of the display device is specified as follows.

A plurality of insulating films 120 such as 122, 123, 124, 125, 126, 127, 128, 129, 130, 131 can be stacked on the display area AA and non-display area NA of the substrate 110, so that the active layers 151, 182, 181 and electrodes 161, 191, 192, 171, 172, 202, 203, 204, 205 constituting the transistors LT, OT1, OT2 can be insulated from each other.

A first insulating film 122 is disposed on the display area AA and non-display area NA on the substrate 110. The first insulating film 122 can be referred to as a buffer film and can have the same function as a buffer film known in the art. The first insulating film 122 can be disposed on the substrate 110 to protect structures located on the substrate 110 from moisture penetrating through the substrate 110 and to flatten the surface of the substrate 110.

The first insulating film 122 can be disposed up to the edge of the substrate 110 to prevent or reduce moisture from penetrating from the edge of the substrate 110. The first insulating film 122 can be a single inorganic film or can be composed of multiple inorganic films that are alternately stacked.

For example, the first insulating film 122 can include at least one inorganic film of a silicon oxide film (SiOx), a silicon nitride film (SiNx), or a silicon oxynitride film (SiOxNy), or can include a multilayer film in which the inorganic films described above are stacked.

The first light shielding pattern 141 can be disposed on the first insulating film 122. For example, the first light shielding pattern 141 can be made of a conductive metal material, and the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The conductive metal material can be provided in a monolayer or multilayer structure.

A second insulating film 123 can be disposed on the first insulating film 122 and the first light shielding pattern 141. The second insulating film 123 can function as, for example, a second buffer layer. The second insulating film 123 can include an inorganic film, for example, a silicon oxide film (SiOx), a silicon nitride film (SiNx), or a multilayer film thereof.

The first active layer 151 made of polycrystalline silicon can be provided on the second insulating film 123. The first active layer 151 can be polycrystalline by depositing amorphous silicon on the second insulating film 123 followed by crystallization.

A third insulating film 124 can be disposed on the second insulating film 123 and the first active layer 151. The third insulating film 124 can be used as a gate insulating film of the polycrystalline transistor LT. The third insulating film 124 can include an inorganic material. The inorganic material can include, for example, a silicon nitride film (SiNx).

The first gate electrode 161 and the second light shielding pattern 162 can be provided on the third insulating film 124. The first gate electrode 161 and the second light shielding pattern 162 can be formed of, for example, a conductive metal material, and specifically, the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The conductive metal material can be provided in a monolayer or multilayer structure.

Fourth and fifth insulating films 125, 126 can be disposed on the third insulating film 124. The fourth and fifth insulating films 125, 126 can be made of an inorganic insulating material. For example, the fourth insulating film 125 can be a silicon nitride film, and the fifth insulating film 126 can be a silicon oxide film. The fourth and fifth insulating films 125, 126 can also function as interlayer insulating films of the polycrystalline transistor LT.

The first source drain electrode 171 and the first connection electrode 172 can be formed on the fifth insulating film 126 using a conductive metal material. Specifically, the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The conductive metal material can be provided in a monolayer or multilayer structure.

The first source drain electrode 171 can be connected to the first active layer 151 through a contact hole 171a formed in the fifth insulating film 126, the fourth insulating film 125, and the third insulating film 124.

For example, the first connection electrode 172 can be connected to the first gate electrode 161 through a contact hole 172a formed in the fifth insulating film 126 and the fourth insulating film 125, and can be connected to the first light shielding pattern 141 through a contact hole 172b formed in the fifth insulating film 126, the fourth insulating film 125, the third insulating film 124, and the second insulating film 123.

The third light shielding pattern 173 can be provided on the fifth insulating film 126 using the same material as the first source drain electrode 171 and the first connection electrode 172.

A sixth insulating film 127 and a seventh insulating film 128 can be provided on the fifth insulating film 126. The sixth and seventh insulating films 127, 128, including an inorganic insulating material, can serve to protect the polycrystalline transistor LT and achieve surface planarization of the first and second oxide transistors OT1, OT2, and can function as a buffer film. For example, in order to prevent the influence of hydrogen flow due to the insulating film included in the polycrystalline transistor LT on the first and second oxide transistors OT1, OT2, at least the seventh insulating film 128 in contact with the lower surface of the second and third active layers 182, 181 of the first and second oxide transistors OT1, OT2 can be a silicon oxide film. The sixth insulating film 127 can be a silicon oxide film or a silicon nitride film.

The second active layer 182 and the third active layer 181 are formed on the seventh insulating film 128 using an oxide semiconductor. The oxide semiconductor can be formed by a combination of at least one metal selected from the group consisting of zinc (Zn), indium (In), gallium (Ga), tin (Sn), and titanium (Ti) and an oxide. In some cases, a metal having high conductivity, such as iron (Fe), etc., can be further included in the oxide semiconductor material, increasing carrier mobility.

More specifically, examples of the oxide semiconductor material constituting the second and third active layers 182, 181 include zinc oxide (ZnO), zinc tin oxide (ZTO), zinc indium oxide (ZIO), indium oxide (InO), titanium oxide (TiO), indium gallium zinc oxide (IGZO), indium zinc tin oxide (IZTO), iron indium zinc oxide (FIZO), etc.

In addition, the hydrogen capture pattern 280 is provided on the seventh insulating film 128 corresponding to the transmissive area TA. The hydrogen capture pattern 280 selectively transmits light received or sensed by the transmissive area TA or the sensor portions A1, A2 and can be made of, for example, indium oxide. The hydrogen capture pattern 280 can include a material having higher hydrogen capture capability than the oxide semiconductor forming the second and third active layers 182, 181 in order to further prevent hydrogen or reduce transfer to the second and third active layers 182, 181 provided at the second sub-pixel SP2 adjacent to the transmissive area TA.

An eighth insulating film 129 is provided on the hydrogen capture pattern 280, the second active layer 182, and the third active layer 181. The eighth insulating film 129 can function as a gate insulating film of the first and second oxide transistors OT1, OT2. The eighth insulating film 129 includes an inorganic insulating material. The eighth insulating film 129 can be a silicon oxide film to minimize the influence of hydrogen on the second and third active layers 182, 181.

As illustrated, the eighth insulating film 129 can be formed to cover the upper and side surfaces of the hydrogen capture pattern 280 and the second and third active layers 182, 181 made of the oxide semiconductor. The eighth insulating film 129 can be formed throughout the entirety of the display area AA and non-display area NA by extending to the side. In some cases, the eighth insulating film 129 can be provided only between the channel region of the second and third active layers 182, 181 and the second and third gate electrodes 191, 192 formed subsequently.

The eighth insulating film 129 can be provided in a multilayer structure. When the eighth insulating film 129 has a multilayer structure, the insulating film in contact with the second and third active layers 182, 181 can be an inorganic insulating film with low hydrogen content.

The second and third gate electrodes 191, 192 overlapping respective portions of the second and third active layers 182, 181 can be provided on the eighth insulating film 129.

The second and third gate electrodes 191, 192 can be formed of a conductive metal material. Specifically, the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The second and third gate electrodes 191, 192 can have a multilayer film structure including at least two conductive metal materials. The conductive metal material can be provided in a monolayer or multilayer structure.

When the second and third active layers 182, 181 are doped with impurities using the second and third gate electrodes 191, 192 as masks, the channel of the second and third gate electrodes 191, 192 can be a region overlapping the second and third gate electrodes 191, 192. The region of the second and third active layers 182, 181 overlapping the second and third gate electrodes 191, 192 is not doped with impurities and functions as a channel of the oxide semiconductor layer.

The region doped with impurities in the second and third active layers 182, 181 can then be connected to the second and third source drain electrodes 202, 203 and the fourth and fifth source drain electrodes 204, 205, which are spaced apart from each other, and can function as a conductive source drain region.

A ninth insulating film 130 and a tenth insulating film 131 can be sequentially formed on the eighth insulating film 129 and the second and third gate electrodes 191, 192.

The ninth and tenth insulating films 130, 131 can be inorganic insulating films. For example, the ninth and tenth insulating films 130, 131 can include at least one inorganic material selected from among a silicon oxide film (SiOx), a silicon nitride film (SiNx), and a silicon oxynitride film (SiOxNy).

A second connection electrode 201 can be formed on the tenth insulating film 131 to protect and cover the first source drain electrode 171 using a conductive metal material. Specifically, the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The conductive metal material can be provided in a monolayer or multilayer structure.

The second connection electrode 201 can be connected to the first source drain electrode 171 through a contact hole formed in the tenth insulating film 131, the ninth insulating film 130, the eighth insulating film 129, the seventh insulating film 128, and the sixth insulating film 127, and can have both a conductive function and a function of protecting the first source drain electrode 171. Also, the second connection electrode 201 can be located around the transmissive area TA and can function to block impurities such as hydrogen, etc. remaining in the sixth to tenth insulating films 127, 128, 129, 130, 131 at the second sub-pixel SP2 from being transferred to the insulating films at adjacent sides.

The second and third source drain electrodes 202, 203 are connected to the second active layer 182 through a contact hole formed in the tenth insulating film 131, the ninth insulating film 130, and the eighth insulating film 129.

The fourth and fifth source drain electrodes 204, 205 are connected to the third active layer 181 through a contact hole formed in the tenth insulating film 131, the ninth insulating film 130, and the eighth insulating film 129. The fifth source drain electrode 205 can extend further outward than the third active layer 181 and can be connected to the third light shielding pattern 173 located lower than the third active layer 181 through a contact hole formed in the tenth insulating film 131, the ninth insulating film 130, the eighth insulating film 129, the seventh insulating film 128, and the sixth insulating film 127.

Referring to the drawings and experiments, the principle of the hydrogen capture pattern 280 of the transmissive area TA is described as follows.

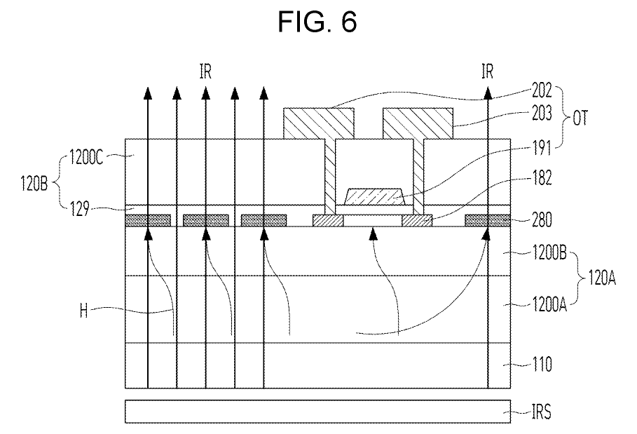

FIG. 6 is a cross-sectional view showing a transistor and a hydrogen capture pattern provided in an area of an infrared sensor IRS according to an embodiment of the present disclosure.

FIG. 6 shows a sensor portion in which an infrared sensor IRS is disposed below the substrate 110. A first insulating film group 120A is disposed between the substrate 110 and the second active layer 182 made of an oxide semiconductor material, and a second insulating film group 120B is disposed on the second active layer 182. The first insulating film group 120A can include a lower insulating film 1200A located under the first source drain electrode 171 of the polycrystalline transistor LT (FIG. 4) and an upper insulating film 1200B located on the first source drain electrode 171.

The lower insulating film 1200A includes a silicon nitride film, and through heat treatment in a hydrogenation process, pores in the first active layer 151 made of polycrystalline silicon can be filled with hydrogen included in the lower insulating film 1200A.

Meanwhile, the second active layer 182 or third active layer 181 that controls carrier mobility through pores in the oxide semiconductor unlike polycrystalline silicon can serve to prevent or reduce the influence of hydrogen H from the insulating film in contact by making the upper insulating film 1200B of the first insulating film group 120A a silicon oxide film, maintain the internal pores, and prevent changes in electrical characteristics.

Also, the second insulating film group 120B can include an interlayer insulating film 1200C and the eighth insulating film 129 closest to the second active layer 182 made of an oxide semiconductor material. The eighth insulating film 129 is in direct contact with the second active layer 182 and can function as a gate insulating film, and can be made of a silicon oxide film with low hydrogen transfer capacity to the second active layer 182.

As shown in FIG. 6, the hydrogen capture pattern 280 made of indium oxide or the like having excellent infrared transmittance is disposed around the second active layer 182 of the oxide transistor OT. When hydrogen H remaining in the first insulating film group 120A between the substrate 110 and the second active layer 182 flows upward during a process such as heat treatment of the oxide transistor OT, hydrogen H can be captured by the hydrogen capture pattern 280 around the oxide transistor OT. In addition, when the hydrogen capture pattern 280 has higher hydrogen capture capability than the second active layer 182, it is possible to prevent the characteristics of the oxide transistor OT including the second active layer 182 from changing due to intensive application of hydrogen to the second active layer 182.

In addition, the hydrogen capture pattern 280 has a transmittance of an infrared IR of about 99% and is responsible for hydrogen capture without reducing the infrared sensitivity of the infrared sensor IRS.

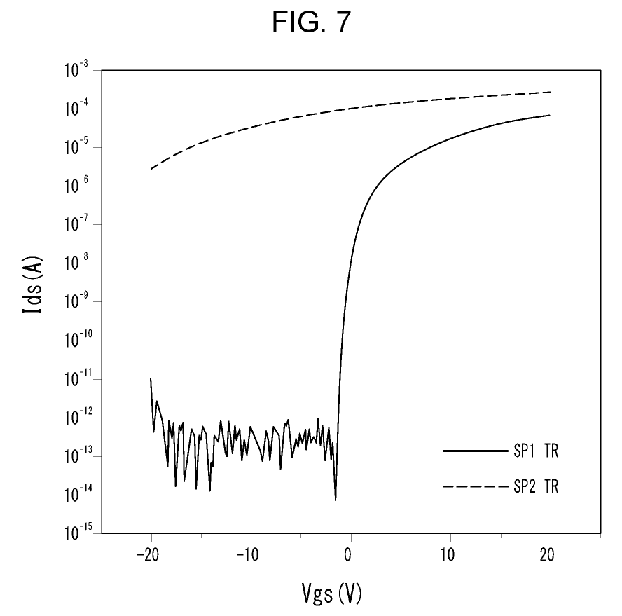

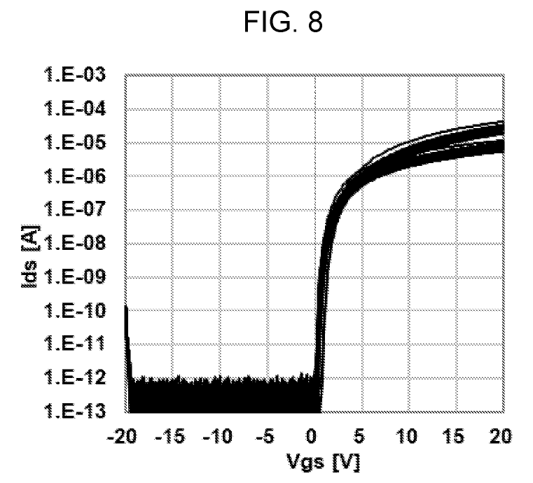

FIG. 7 is a graph showing the I-V characteristics of transistors in the active area of the sensor portion and the non-sensor portion in a display device having no hydrogen capture pattern. FIG. 8 is a graph showing the I-V characteristics of a transistor in a transmissive area of a display device having a hydrogen capture pattern in the transmissive area according to an embodiment of the present disclosure.

As shown in FIG. 7, in the display device of FIG. 1, when the sensor portion has no hydrogen capture pattern, the active area outside the sensor portion includes sub-pixels SP1 densely arranged without a transmissive area, and the oxide transistors among the transistors SP1 TR in the active area outside the sensor portion include an active layer made of an oxide semiconductor material that blocks hydrogen coming from the interlayer insulating film of the lower polycrystalline transistor to a certain extent, so that the current changes depending on a change in gate voltage have on-off characteristics.

On the other hand, in the display device of FIG. 1, when the sensor portion has no hydrogen capture pattern, the active area in the sensor portion includes no sub-pixel SP2 disposed in the transmissive area, and thus the arrangement density of the transistors SP2 TR of the sensor portion is low, and the active layers made of the oxide semiconductor material of the oxide transistors among the transistors of the sensor portion are disposed sparsely, so that hydrogen passing through the first insulating film group 120A is intensively applied to the transistors SP2 TR in the sensor portion, incurring a problem in which the active layer made of the oxide semiconductor layer material loses internal channel characteristics and becomes conductive, like the transistors SP2 TR in the sensor portion of FIG. 7.

The display device according to an embodiment of the present disclosure includes the hydrogen capture pattern 280 provided in the transmissive area as shown in FIGS. 1 to 4, thereby blocking hydrogen from flowing into the oxide semiconductor layer of transistors in the sensor portion provided at a low arrangement density around the transmissive area, so that on-off characteristics depending on a change in gate voltage can be stably maintained by the transistors in the sensor portion, as shown in FIG. 8.

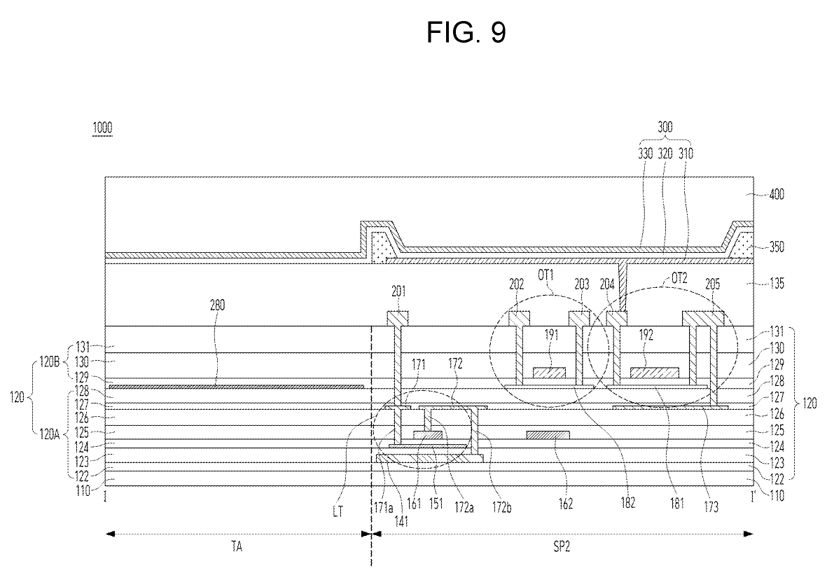

FIG. 9 is a cross-sectional view showing a display device according to an embodiment of the present disclosure.

As shown in FIG. 9, the display device 1000 according to an embodiment of the present disclosure is configured to further include a light emitting device 300 (ED in FIG. 3) connected to the second oxide transistor OT2 compared to the structure of the display device described in FIG. 4.

An additional configuration except for the same configuration described above is described.

As shown in FIG. 9, a planarization film 135 can be provided over the transistors LT, OT1 and OT2. The planarization film 135 can be on the second connection electrode 201 and the second to fifth source drain electrodes 202, 203, 204, 205 to achieve surface planarization.

The planarization film 135 can include an organic material. The organic material can include at least one selected from among an acrylic resin, a phenolic resin, a polyimide resin, an unsaturated polyester resin, a polyamide resin, a benzocyclobutene resin, a polyphenylene resin, and a polyphenylene sulfide resin.

The planarization film 135 can have a monolayer or multilayer structure. When the planarization film 135 has a multilayer structure, some of the layers of the planarization film are further provided with a connection electrode, and the fourth source drain electrode 204 at the lower position and the first electrode 310 of the light emitting device ED can be connected.

The light emitting device 300 (ED in FIG. 3) can be disposed on the planarization film 135.

The first electrode 310 is further provided on the planarization film 135 and can be connected to one among the second to fifth source drain electrodes 202, 203, 204, 205 through a contact hole in the planarization film 135.

The first electrode 310 can be an anode. The first electrode 310 can include, for example, a reflective electrode and can function to block light from being incident on the transistors LT, OT1 and OT2 below the light emitting device 300. The first electrode 310 can have, for example, a stack structure of a first transparent electrode, a reflective electrode, and a second transparent electrode. The second transparent electrode, which is the uppermost electrode of the first electrode 310, can serve to lower the barrier for hole injection at the interface with the intermediate layer 320 as a dielectric. Here, the first and second transparent electrodes can be transparent oxide electrodes made of ITO, IZO, etc. The reflective electrode can include silver, a silver alloy such as APC (Ag-Pd-Cu), aluminum, or an aluminum alloy.

A bank 350 is provided at the edge of the first electrode 310, and at least the open area of the bank 350 in the second and first sub-pixels SP2, SP1 can function as an emissive portion.

Also, the bank 350 can include a light shielding bank, or can include a transparent bank and a light shielding bank, blocking light passing through the second sub-pixel SP2 in the sensor portion through the light shielding bank from entering the transmissive area of the adjacent sensor portion.

The light emitting device ED (300) includes the first electrode 310, an intermediate layer 320, and a second electrode 330. After the bank 350 that opens the emissive portion is disposed at the edge of the first electrode 310, the intermediate layer 320 and the second electrode 330 can be sequentially disposed.

For sake of process integrity, the intermediate layer 320 and the second electrode 330 can be disposed not only in the second and first sub-pixels SP2, SP1 but also in the transmissive area TA, but the display device according to an embodiment of the present disclosure is not limited thereto. Other arrangements of the transmissive area TA are described later.

The intermediate layer 320 can include a hole injection layer, a hole transport layer, an emission layer, an electron transport layer, and an electron injection layer. The intermediate layer 320 can be provided in the form of a plurality of stacks including a hole transport layer, an emission layer, and an electron transport layer, and can also be formed in a tandem structure including a charge generation layer between the stacks. The charge generation layer can include, for example, an n-type charge generation layer and a p-type charge generation layer.

The second electrode 330 can be provided by forming a transparent electrode made of ITO, IZO, etc. or a reflective transparent electrode made of silver, a silver alloy, magnesium, a magnesium alloy, ytterbium (Yb), or an ytterbium alloy at a low thickness. In another embodiment, the second electrode 330 can be formed at a low thickness or by partial removal in the transmissive area TA to increase the transmittance in the transmissive area TA.

One of the first electrode 310 and the second electrode 330 can be an anode, and the other can be a cathode.

A capping layer can be further formed on the second electrode 330 to protect the second electrode 330 of the light emitting device 300(ED) and increase light extraction efficiency upward.

An encapsulation layer 400 can be provided on the second electrode 330 to prevent moisture penetration into the internal structure and protect the internal structure from external air.

For example, the encapsulation layer 400 can be configured such that inorganic and organic films are stacked. However, the present or reduce disclosure is not limited thereto, and the encapsulation layer 400 can include an encapsulation substrate made of glass, etc. The encapsulation substrate can further include an adhesive layer provided between the same and the facing the light emitting device 300.

In the display device of FIG. 9, the intermediate layer 320 and the second electrode 330 provided in the adjacent sub-pixel SP2 are shown in a state of extending to the transmissive area TA. As such, the processes of the intermediate layer 320 and the second electrode 330 of the other first and second sub-pixels SP1, SP2 and the transmissive area TA can be integrated, achieving process optimization.

Different arrangements of the transmissive area TA are described as follows.

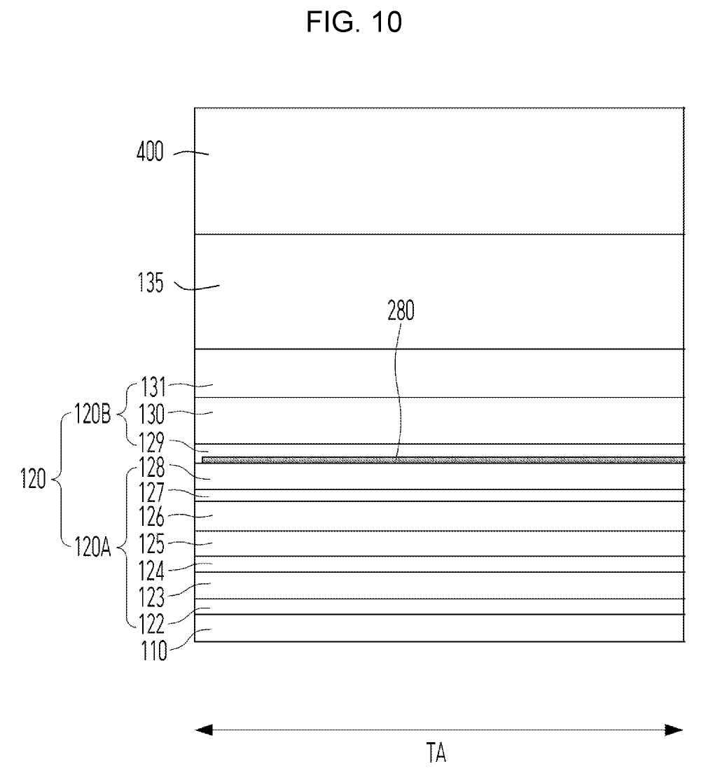

FIGS. 10 to 12 are cross-sectional views of the transmissive area according to various embodiments of the present disclosure.

As shown in FIG. 10, in the display device according to an embodiment of the present disclosure, the transmissive area TA can be configured such that a planarization film 135 is provided on an insulating film 120 made of an inorganic insulating film material and an encapsulation layer 400 is directly disposed on the planarization film 135 without a light emitting device 300.

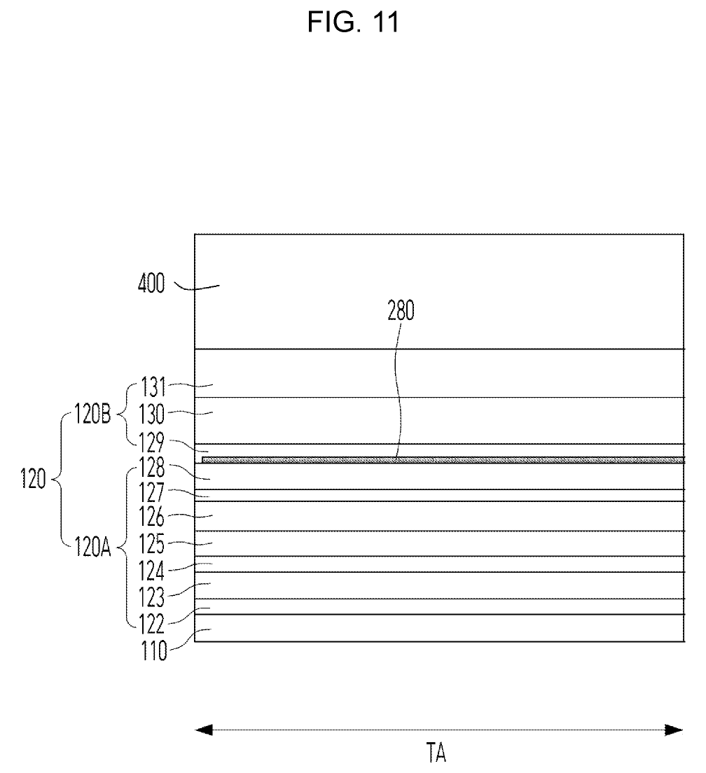

As shown in FIG. 11, in order to further increase the transmittance of the transmissive area TA in the display device according to an embodiment of the present disclosure, without the planarization film 135 and the light emitting device 300 on the insulating film 120 made of the inorganic insulating film material, the encapsulation layer 400 can be directly disposed on the insulating film 120.

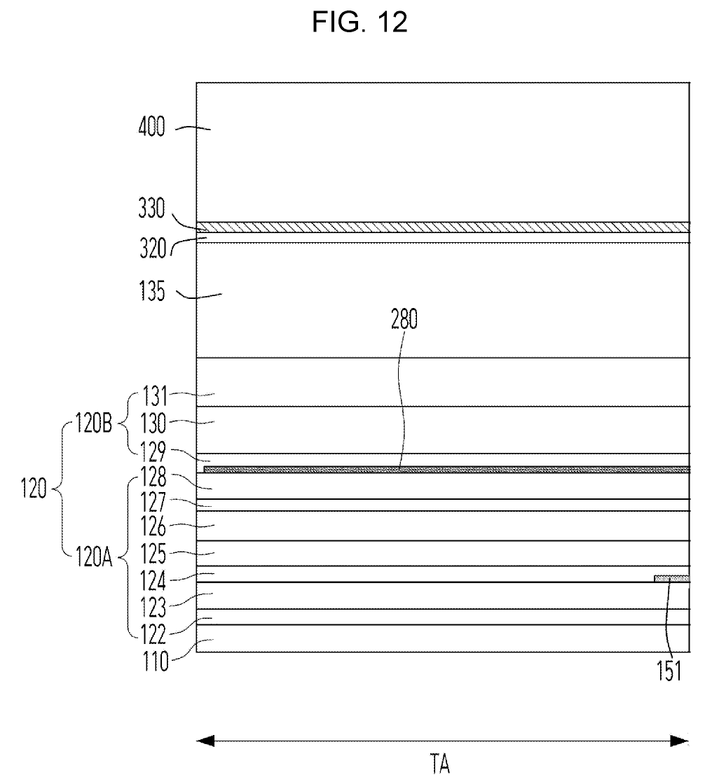

As shown in FIG. 12, the display device according to an embodiment of the present disclosure has, compared to the display device described in FIG. 9, a partial overlap between the hydrogen capture pattern 280 and the first active layer 151 made of polycrystalline silicon. When there is an overlap between the first active layer 151 and the hydrogen capture pattern 280, hydrogen flowing upward through the first active layer 151 or the first insulating film group 120A adjacent to the first active layer 151 can be more easily captured by the hydrogen capture pattern 280.

Meanwhile, although the stability of the oxide transistor located at the upper position among the transistors mainly disposed in the sub-pixels in the display device according to embodiments of the present disclosure has been described above, the embodiments of the present disclosure are not limited thereto.

For example, for transistors located in the non-display area NA, such as a gate-in-panel, when the polycrystalline transistor LT and the oxide transistors OT1, OT2 are provided together as shown in FIG. 4, a hydrogen capture pattern can be further provided around the oxide semiconductor layer of the oxide transistors OT1, OT2 to prevent or reduce hydrogen flowing in the first insulating film group 120A included in the polycrystalline transistor LT located at the lower position from affecting the characteristics of the oxide transistors OT1, OT2 at the upper position.

The display device according to embodiments of the present disclosure can have a hydrogen capture pattern corresponding to the sensor portion, thereby blocking the influence of hydrogen generated below or around transistors in an area where the transistors are provided at a low density. Accordingly, the transistors located in the sensor portion can be prevented from being deteriorated by hydrogen, thereby stably maintaining I-V characteristics and preventing changes in on-off characteristics and threshold voltage.

Also, in the display device according to embodiments of the present disclosure, the hydrogen capture pattern is located on the same layer as the active layer including the oxide semiconductor layer, so that the hydrogen capture pattern is able to prevent or reduce the array configuration including the polycrystalline silicon layer at the lower position from generating gases such as hydrogen during a thermal process, etc., around the active layer at a low arrangement density.

In the display device according to embodiments of the present disclosure, the hydrogen capture pattern is formed of an oxide material containing indium to increase infrared transmittance as well as the hydrogen capture function, thereby increasing infrared sensitivity of the sensor portion and improving the sensing function. In addition, the hydrogen capture pattern is disposed at a higher position than the active layer including the polycrystalline silicon layer having high hydrogen content and at least one insulating layer on the active layer including the polycrystalline silicon layer, making it possible to prevent or reduce hydrogen generated from a transistor including the polycrystalline silicon layer from affecting a transistor including the oxide semiconductor layer.

A display device according to one embodiment of the present disclosure can comprise a substrate comprising a display area and a non-display area surrounding the display area, a sensor portion having a transmissive area at the display area, a plurality of first transistors provided in the display area on the substrate and comprising an oxide semiconductor layer and a hydrogen capture pattern located in the transmissive area and disposed planarly adjacent to the oxide semiconductor layer of at least one of the plurality of first transistors.

In a display device according to one embodiment of the present disclosure, the hydrogen capture pattern can comprise a conductive oxide.

In a display device according to one embodiment of the present disclosure, the hydrogen capture pattern can comprise a conductive oxide containing indium.

In a display device according to one embodiment of the present disclosure, the hydrogen capture pattern can comprise a material having transmittance at an infrared wavelength range.

In a display device according to one embodiment of the present disclosure, the hydrogen capture pattern can be located at a same layer as the oxide semiconductor layer of the plurality of first transistors.

In a display device according to one embodiment of the present disclosure, the hydrogen capture pattern can have higher hydrogen capture capability than the oxide semiconductor layer of the plurality of first transistors.

In a display device according to one embodiment of the present disclosure, the sensor portion can be located below the substrate and the hydrogen capture pattern overlaps the sensor portion.

A display device according to one embodiment of the present disclosure can further comprise a polycrystalline silicon layer between the substrate and the oxide semiconductor layer. At least one inorganic insulating film can be disposed between the oxide semiconductor layer and the polycrystalline silicon layer.

In a display device according to one embodiment of the present disclosure, at least a portion of the polycrystalline silicon layer can overlap the hydrogen capture pattern.

In a display device according to one embodiment of the present disclosure, the oxide semiconductor layer of the plurality of first transistors can comprise a first active layer and a second active layer having different carrier mobilities at different areas.

A display device according to one embodiment of the present disclosure can further comprise a second transistor comprising a polycrystalline silicon layer between the substrate and the oxide semiconductor layer of the plurality of first transistors corresponding to the display area.

In a display device according to one embodiment of the present disclosure, the display area can comprise a first area where the sensor portion is disposed and a second area where the sensor portion is not disposed. The first area of the substrate can comprise the transmissive area and a plurality of first emissive portions, the second area of the substrate can comprise a plurality of second emissive portions. And at the first area, electrodes of the first transistors and the second transistor need not overlap the transmissive area.

In a display device according to one embodiment of the present disclosure, at the first area, the hydrogen capture pattern can be disposed between oxide semiconductor layers of the adjacent first transistors.

In a display device according to one embodiment of the present disclosure, a density of the first transistors at the first area can be less than a density of transistors comprising the oxide semiconductor layer at the second area.

In a display device according to one embodiment of the present disclosure, each of the first emissive portions and the second emissive portions can be connected to any one of the first transistors.

In a display device according to one embodiment of the present disclosure, the hydrogen capture pattern can be divided into multiple pieces at the transmissive area, and a width “a” of each of the divided hydrogen capture pattern pieces is greater than a spacing “s” between adjacent hydrogen capture pattern pieces.

A display device according to one embodiment of the present disclosure can further comprise a second transistor comprising polycrystalline silicon layer between the substrate and the oxide semiconductor layer of the first transistors at the non-display area of the substrate, and a third transistor comprising an active layer disposed on a same layer as the oxide semiconductor layer of the first transistors.

In a display device according to one embodiment of the present disclosure, carrier mobility of the oxide semiconductor layer of the first transistors can be different from carrier mobility of the active layer of the third transistor.

A display device according to one embodiment of the present disclosure can further comprise a planarization film over the first transistors and the hydrogen capture pattern. Each of the first emissive portions and the second emissive portions can comprise a light emitting device on the planarization film, the light emitting device comprising an anode, an intermediate layer, and a cathode. Any one of the first transistors and the anode can be connected through a contact hole in the planarization film.

As is apparent from the foregoing, a display device according to embodiments of the present disclosure has the following effects.

First, the display device according to embodiments of the present disclosure has a hydrogen capture pattern corresponding to a sensor portion, blocking the influence of hydrogen generated below or around transistors in an area where the transistors are provided at a low density. Accordingly, the transistors located in the sensor portion can be prevented from being deteriorated by hydrogen, thereby stably maintaining I-V characteristics and preventing or reducing changes in on-off characteristics and threshold voltage.

Second, the hydrogen capture pattern is located on the same layer as the active layer including the oxide semiconductor layer, so that the hydrogen capture pattern is able to prevent or reduce an array configuration including the polycrystalline silicon layer at a lower position from generating gases such as hydrogen during a thermal process, etc. around the active layer at a low arrangement density.

Third, the hydrogen capture pattern is formed of an oxide material containing indium, increasing the infrared transmittance as well as the hydrogen capture function, thereby increasing the infrared sensitivity of the sensor portion and improving the sensing function.

Fourth, the hydrogen capture pattern is disposed at a higher position than the active layer including the polycrystalline silicon layer having high hydrogen content and at least one insulating layer on the active layer including the polycrystalline silicon layer, preventing or reducing hydrogen generated from a transistor including the polycrystalline silicon layer from affecting a transistor including the oxide semiconductor layer.

Fifth, by providing the hydrogen capture pattern on the same layer as the oxide semiconductor in areas where the arrangement density of transistors including the oxide semiconductor is different, the influence of the lower array in areas where the arrangement density of transistors is different can become uniform, thereby controlling abnormal characteristics of the transistors in each area.

Sixth, the display device according to embodiments of the present disclosure can be formed by the same process as the formation of the oxide semiconductor without adding additional materials, thereby enabling implementation of a uni-material.

In addition, in the display device according to embodiments of the present disclosure, the number of processes required for additional materials can be reduced, energy consumed to produce the same can be lowered, and generation of greenhouse gases during the manufacturing process can be reduced through process optimization, thereby achieving ESG (environmental/social/governance) goals.

Through the above description, it should be apparent to those skilled in the art that various changes and modifications are possible without departing from the technical spirit of the present disclosure. Therefore, the technical scope of the present disclosure should not be limited to the above detailed description, but should be defined by the scope of the claims.

What is claimed is:

1. A display device, comprising:
a substrate comprising a display area and a non-display area outside the display area;
a sensor portion having a transmissive area at the display area;
a plurality of first transistors provided in the display area on the substrate and comprising oxide semiconductor layers, respectively; and
a hydrogen capture pattern located in the transmissive area and disposed planarly adjacent to an oxide semiconductor layer of at least one of the plurality of first transistors.

2. The display device according to claim 1, wherein the hydrogen capture pattern comprises a conductive oxide.

3. The display device according to claim 1, wherein the hydrogen capture pattern comprises a conductive oxide containing indium.

4. The display device according to claim 1, wherein the hydrogen capture pattern comprises a material having transmittance of light at an infrared wavelength range.

5. The display device according to claim 1, wherein the hydrogen capture pattern has higher hydrogen capture capability than the oxide semiconductor layers of the plurality of first transistors.

6. The display device according to claim 1, further comprising a sensor located below the substrate,
wherein the hydrogen capture pattern overlaps the sensor.

7. The display device according to claim 1, further comprising a polycrystalline silicon layer between the substrate and the oxide semiconductor layer,
wherein at least one inorganic insulating film is disposed between the oxide semiconductor layer and the polycrystalline silicon layer.

8. The display device according to claim 7, wherein at least a portion of the polycrystalline silicon layer overlaps the hydrogen capture pattern.

9. The display device according to claim 1, wherein the oxide semiconductor layer of the at least one of the plurality of first transistors comprises a first active layer and a second active layer having different carrier mobilities.

10. The display device according to claim 1, further comprising a second transistor comprising a polycrystalline silicon layer between the substrate and the oxide semiconductor layers of the plurality of first transistors corresponding to the display area.

11. The display device according to claim 10, wherein:
the display area comprises a first area where the sensor portion is disposed and a second area where the sensor portion is not disposed,
the first area comprises the transmissive area and a plurality of first emissive portions,
the second area comprises a plurality of second emissive portions, and
at the first area, electrodes of the plurality of first transistors and the second transistor do not overlap the transmissive area.

12. The display device according to claim 11, wherein, at the first area, the hydrogen capture pattern is disposed between the oxide semiconductor layers of adjacent first transistors of the plurality of first transistors.

13. The display device according to claim 11, wherein a density of the plurality of first transistors at the first area is less than a density of transistors comprising an oxide semiconductor layer at the second area.

14. The display device according to claim 11, wherein each of the plurality of first emissive portions and the plurality of second emissive portions is connected to any one of the plurality of first transistors.

15. The display device according to claim 1, wherein the hydrogen capture pattern is divided into pieces at the transmissive area, and a width of each of the divided pieces of the hydrogen capture pattern is greater than a spacing between adjacent pieces of the hydrogen capture pattern.

16. The display device according to claim 1, further comprising a second transistor comprising a polycrystalline silicon layer between the substrate and the oxide semiconductor layer of the at least one of the plurality of first transistors at the non-display area of the substrate, and a third transistor comprising an active layer disposed on a same layer as the oxide semiconductor layer of the at least one of the plurality of first transistors.

17. The display device according to claim 16, wherein carrier mobility of the oxide semiconductor layer of the at least one of the plurality of first transistors is different from carrier mobility of the active layer of the third transistor.

18. The display device according to claim 11, further comprising a planarization film over the plurality of first transistors and the hydrogen capture pattern,
wherein each of the plurality of first emissive portions and the plurality of second emissive portions comprises a light emitting device on the planarization film, the light emitting device comprising an anode, an intermediate layer, and a cathode, and
wherein any one of the plurality of first transistors and the anode are connected through a contact hole in the planarization film.

19. A display device, comprising:
a display area and a non-display area outside the display area;
a sensor portion located at the display area and having a transmissive area and an emissive portion placement area;
at least one transistor provided in the emissive portion placement area and comprising an oxide semiconductor layer; and
a hydrogen capture pattern located in the transmissive area and disposed not to overlap the oxide semiconductor layer.

20. The display device according to claim 19, wherein a transmittance of infrared light is about 99% in the hydrogen capture pattern.
